(19) United States
(12) Patent Application Publication
(10) Pub. No.: US 2012/0236623 A1
(43) Pub. Date: Sep. 20, 2012

(54) SENSING RESISTIVE STATES

(76) Inventor: Muhammad Shakeel Qureshi, Santa Clara, CA (US)

(21) Appl. No.: 13/050,349

(22) Filed: Mar. 17, 2011

(51) Int. Cl. G11C 11/00

(52) U.S. Cl. 365/148

(57) ABSTRACT

A memory device capable of being sensed with an oscillating signal includes a first terminal of a memristive element connected to an oscillating signal supply, and a second terminal of the memristive element connected to sensing circuitry, the sensing circuitry to determine an attenuation of an oscillating signal from the oscillating signal supply. A crossbar array includes a first set of parallel lines selectively connected to an oscillating signal supply, a second set of parallel lines intersecting the first set of parallel lines, the second set of parallel lines selectively connected to sensing circuitry, memristive memory elements being disposed at crosspoints between the first set of parallel lines and the second set of parallel lines, in which a memory controller of the crossbar array is to determine a resistive state of one of the memory elements by determining, with the sensing circuitry, an attenuation of an oscillating signal produced by the oscillating signal supply.

### STATEMENT OF GOVERNMENT INTEREST

This invention has been made with government support under Contract No. HR0011-09-3-0001, awarded by the Defense Advanced Research Project Agency. The government has certain rights in the invention.

### BACKGROUND

As the use of digital data increases, the demand for faster, smaller, and more efficient memory structures used for storing that digital data increases. One type of memory structure which has recently been developed is a crossbar memory structure. A crossbar memory structure includes a set of upper parallel wires which intersect a set of lower parallel wires. A memory element is placed at the intersections between the upper and lower parallel lines. The programmable memory element may store digital data.

One type of programmable memory element which may be used is a memristive element. A memristive element is a device which changes the state of its resistance based on an applied programming condition. For example, a programming condition may be applied to change the memristive element from a high resistive state to a low resistive state or vice versa. A high resistive state may represent a digital “1” and a low resistive state may represent a digital “0”.

One challenge that results from use of a crossbar memory structure is the process of reading the state of a specific memory element within that crossbar array. The state of a memory element can be determined by applying a sensing condition such as a sense voltage or a sense electric current. However, a Direct Current (DC) signal applied to a memory element within the crossbar array leaks to other memory elements within the array. This makes it difficult to determine how an applied signal is being affected by one particular memory element. The additional circuitry to isolate a particular memory element within the array consumes additional power and takes up additional space.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 is a diagram showing an illustrative crossbar array, according to one example of principles described herein.

FIG. 2 is a diagram showing an illustrative circuit schematic of a low pass filter, according to one example of principles described herein.

FIG. 3A is a diagram of an illustrative graph showing corner frequencies, according to one example of principles described herein.

FIG. 3B is a diagram of an illustrative graph showing oscillatory signals sensed from a memristive device, according to one example of principles described herein.

FIG. 4 is a diagram showing an illustrative schematic of a crossbar array with oscillatory signal sensing, according to one example of principles described herein.

FIG. 5 is a flowchart showing an illustrative method for using an oscillatory signal to sense the state of a memristive device, according to one example of principles described herein.

Throughout the drawings, identical reference numbers designate similar, but not necessarily identical, elements.

### DETAILED DESCRIPTION

As mentioned above, one challenge that results from use of a crossbar memory structure is the process of reading the state of a specific memory element within that crossbar array. The state of a memory element can be determined by applying a sensing condition such as a sense voltage or a sense electric current. However, a DC signal applied to a memory element within the crossbar array leaks to other memory elements within the array. This makes it difficult to determine how an applied signal is being affected by one particular memory element. The additional circuitry needed to isolate a particular memory element within the array consumes additional power and takes up additional space.

In light of this and other issues, the present specification discloses systems and methods that involve the use of an oscillating signal to sense the state of a memristive device. According to certain illustrative examples, an oscillating signal is applied to one terminal of a memristive device. Additionally, a sensing device is connected to a second terminal of the memristive device. In this configuration, the memristive device acts as a low pass filter.

A low pass filter is a circuit that lets lower frequencies pass through with little or no attenuation while higher frequencies are prohibited from passing through. As the frequency increases, the amplitude of the signal passing through the low pass filter attenuates. The frequency at which the signal becomes attenuated to a particular level is referred to as the corner frequency. The corner frequency is affected in part by the resistive state of the memristive device forming part of the low pass filter. Particularly, a high resistive state of the memristive device will lead to a lower corner frequency. Conversely, a low resistive state of the memristive device will give the low pass filter a higher corner frequency.

To sense the resistive state of a memristive device, the frequency of the oscillating signal applied to the memristive device can be set somewhere between the corner frequencies of the high resistive state and the low resistive state. Thus, the degree of attenuation of the sensed signal will be indicative of the resistive state of the memristive device.

Through use of methods and systems embodying principles described herein, the resistive state of a memristive device can be determined through use of an oscillating signal. When used to determine the state of memristive memory elements in a crossbar array, no circuitry is needed to isolate selected memory elements from leakage currents. Thus, the crossbar array will consume less power and take up less space.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Throughout this specification and in the appended claims, the term “crossbar array” is to be broadly interpreted as a first set of lines intersecting a second set of lines. A programmable logic device is disposed at each crosspoint between a line from the first set and a line from the second set.

Throughout this specification and in the appended claims, the terms “row lines” and “column lines” are used to differentiate between a first set of parallel lines intersecting a second set of parallel lines.

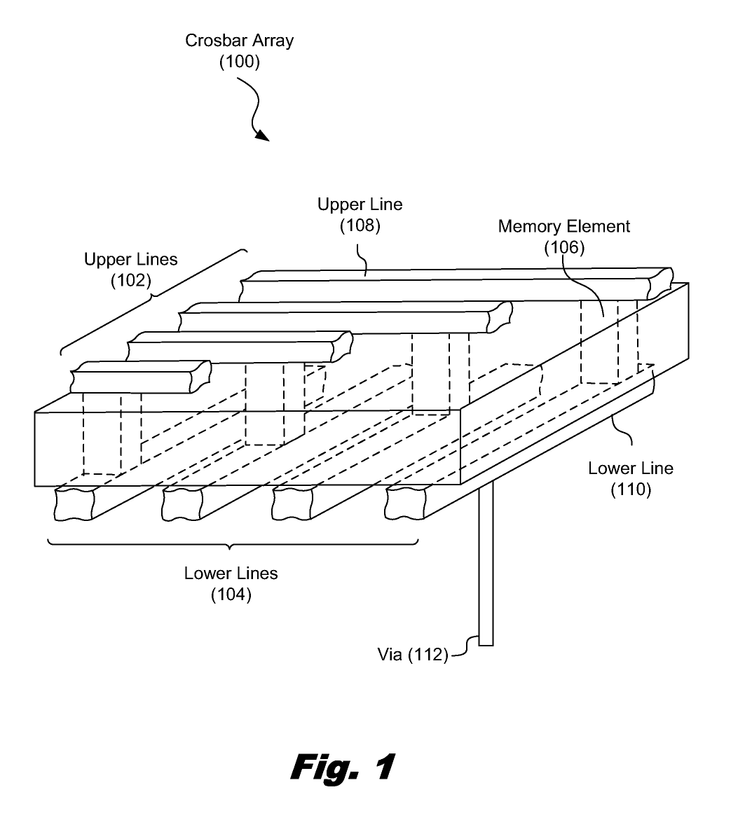

Referring now to the figures, FIG. 1 is a diagram showing Illustrative crossbar memory architecture (100). According to certain illustrative examples, the crossbar architecture (100) may include an upper set of lines (102) which may generally be in parallel. Additionally, a lower set of lines (104) is generally perpendicular to, and intersects, the upper lines (102). Programmable memory devices (106) are formed at the intersections between an upper line (108) and a lower line (110). The terms “upper” and “lower” represent positioning of the lines relative to each other and not necessarily an orientation of the crossbar array as a whole.

According to certain illustrative examples, the programmable memristive devices (106) may be resistive devices such as memristive devices. Memristive devices exhibit a “memory” of past electrical conditions. For example, a memristive device may include a matrix material which contains mobile dopants. These dopants can be moved within a matrix to dynamically alter the electrical operation of an electrical device.

The motion of dopants can be induced by the application of a programming condition such as an applied electrical voltage across the memristive matrix material. The programming voltage generates a relatively high electrical field through the memristive matrix and alters the distribution of dopants. After removal of the electrical field, the location and characteristics of the dopants remain stable until the application of another programming electrical field. For example, by changing the dopant configurations within a memristive matrix, the electrical resistance of the device may be altered. The memristive device is read by applying a lower reading voltage which allows the internal electrical resistance of the memristive device to be sensed but does not generate a high enough electrical field to cause significant dopant motion. Consequently, the state of the memristive device may remain stable over long time periods and through multiple read cycles.

According to certain illustrative examples, the crossbar architecture (100) may be used to form a non-volatile memory array. Non-volatile memory has the characteristic of not losing its contents when no power is being supplied. Each of the programmable memory devices (106) is used to represent one or more bits of data. Although individual crossbar lines (108, 110) in FIG. 1 are shown with rectangular cross sections, crossbars may also have square, circular, elliptical, or more complex cross sections. The lines may also have many different widths, diameters, aspect ratios and/or eccentricities. The crossbars may be nanowires, sub-microscale wires, microscale wires, or wires with larger dimensions.

According to certain illustrative examples, the crossbar architecture (100) may be integrated into a Complimentary Metal-Oxide-Semiconductor (CMOS) circuit or other conventional computer circuitry. Each individual wire segment may be connected to the CMOS circuitry by a via (112). The via (112) may be embodied as an electrically conductive path through the various substrate materials used in manufacturing the crossbar architecture. This CMOS circuitry can provide additional functionality to the memristive device such as input/output functions, buffering, logic, configuration, or other functionality. Multiple crossbar arrays can be formed over the CMOS circuitry to create a multilayer circuit.

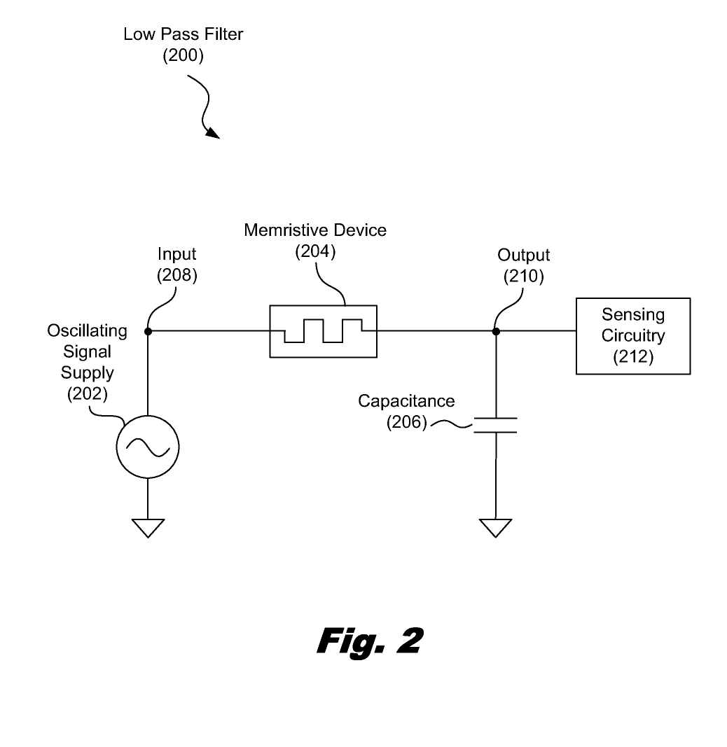

FIG. 2 is a diagram showing an illustrative circuit schematic of a low pass filter (200). As mentioned above, a low pass filter (200) includes a resistance and a capacitance. The resistance aspect of the low pass filter comes from the memristive device and is thus variable. The capacitance (206) can come from the intrinsic capacitance formed at the junction between the output (210) of the low pass filter (200) and sensing circuitry (212).

When an oscillating signal from an oscillating signal supply (202) is applied to the input (208) of a low pass filter, the signal at the output (210) of the low pass filter will depend on the frequency of the applied oscillating signal. At lower frequencies, the signal at the output (210) will not be much different than the signal at the input (208). However, as the frequency increases, the signal at the output (210) will begin to attenuate. The corner frequency is a certain frequency at which the signal at the output (210) attenuates to a certain level. Thus, the low pass filter allows lower frequencies to pass through while higher frequencies are prohibited from passing through.

The corner frequency is affected in part by the resistance element of the low pass filter (200). Thus, the resistive state of the memristive device (204) will affect the corner frequency of the low pass filter (200). Particularly, if the memristive device is in a high resistive state, then the corner frequency will be lower. Conversely, if the memristive device is in a low resistive state, then the corner frequency will be higher. The precise corner frequencies of the two different resistive states will depend on the resistive values of the memristive states as well as the value of the capacitance (206). In some cases, the value of the capacitance (206) may be adjusted through use of a discrete capacitor in addition to any intrinsic capacitance.

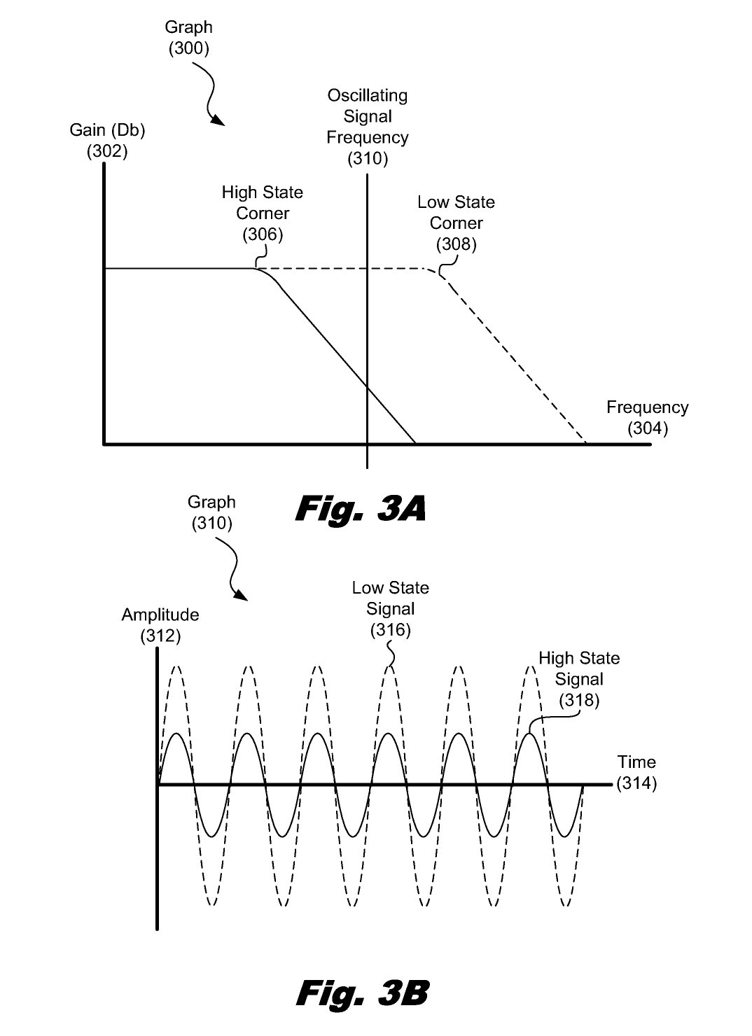

FIG. 3A is a diagram of an illustrative graph showing corner frequencies. The graph (300) represents a bode plot where the vertical axis represents the gain (302) in decibels and the horizontal axis represents the frequency (304) in decades. The solid line represents the frequency response of the low pass filter when the memristive device of that low pass filter is in a high resistive state. The dotted line represents the frequency response of the low pass filter when the memristive device is in a low resistive state.

As can be seen from the graph (300), the corner frequency (306) of the low pass filter in a high resistive state is lower than the corner frequency (308) of the low pass filter in a low resistive state. To determine the state of the memristive device, the frequency (310) of the oscillating signal applied to a particular memristive device can be set somewhere between the high resistive state corner frequency (306) and the low resistive state corner frequency (308). Thus, the resistive state of the memristive device can be determined based on the attenuation of the signal as measured by the sensing circuitry (e.g. 212, FIG. 2) connected to the low pass filter. Particularly, if the signal is sufficiently attenuated, it can be determined that the memristive device is in a high resistive state. If the signal has been only negligibly attenuated, it can be determined that the memristive device is in a low resistive state.

FIG. 3B is a diagram of an illustrative graph (310) showing oscillating signals sensed from a memristive device. The vertical axis of the graph represents the amplitude of a measured signal (312) and the horizontal axis of the graph (310) represents time (314). Furthermore, the dotted line represents the signal (316) as measured by the sensing circuitry when the memristive device is in a low resistive state and the solid line represents the signal (318) as measured by the sensing circuitry when the memristive device is in a high resistive state. As can be seen from the graph (310), the high state signal (318) has been attenuated while the low state signal (316) has not been attenuated.

The sensing circuitry can measure the attenuation of a signal through a variety of means. In one example, the sensing circuitry includes a peak detector. A peak detector is a circuit that is designed to detect peak levels in an oscillating circuit. The peak detector can be designed to detect the peaks in a non-attenuated signal but not the peaks in an attenuated signal. Thus, the peak detector will be able to distinguish between the signal from a memristive device in a high resistive state from the signal from a memristive device in a low resistive state.

In one example, the sensing circuitry includes a sample and hold circuit. A sample and hold circuit is a circuit in which the output signal matches the input signal while in sample mode and holds a value while in hold mode. The value held throughout the hold mode is the value of the input signal at the moment the sample and hold circuit switched from sample mode to hold mode. The timing of the sample and hold circuit can be such that the circuit switches to hold mode at a time that corresponds to the peaks in the oscillating signal flowing from the memristive device. Thus, the value of the output while in hold mode will indicate the peak level of the oscillating signal. If the peak level is relatively low, then it can be determined that the memristive device is in a high resistive state. If the peak level is relatively high, then it can be determined that the memristive device is in a low resistive state.

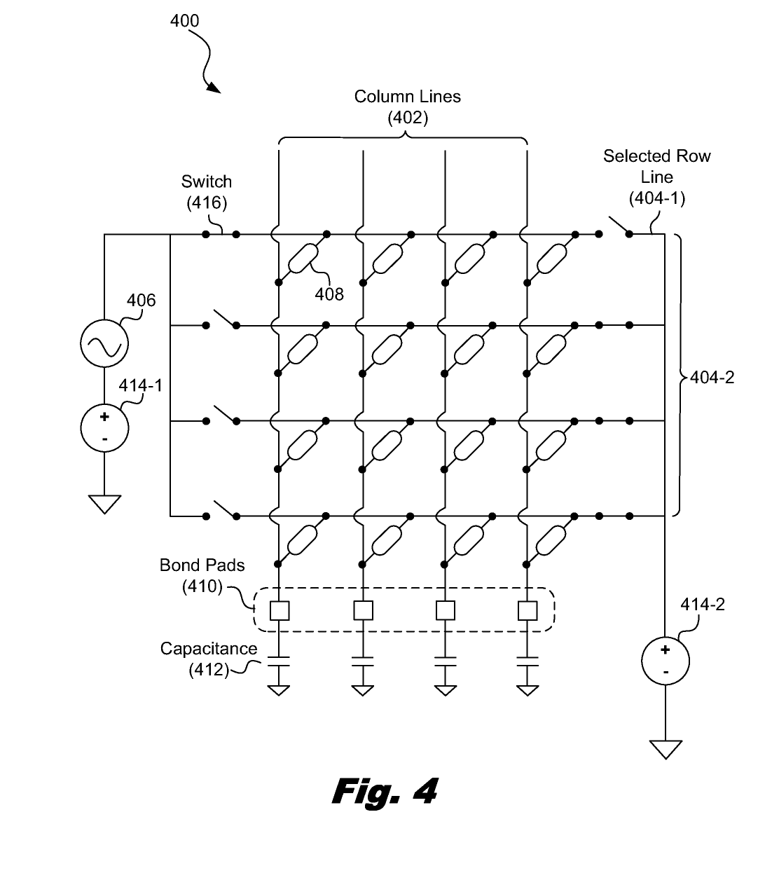

FIG. 4 is a diagram showing an illustrative schematic (400) of a crossbar array with oscillating signal sensing. According to certain illustrative examples, the crossbar array includes a set of row lines (404) and a set of column lines (402). Memory elements (408) are disposed at intersections between the row lines (404) and column lines (402). The row lines (404) are selectively connected to a DC signal supply (414-2). Additionally, the row lines are selectively connected to an oscillating signal supply (406) as well as a DC signal supply (414-1). The column lines (402) are connected to bond pads (410). The bond pads (410) can be used to connect additional circuitry such as sensing circuitry to the crossbar array.

The row lines (404) and the column lines (402) can be used as word lines and bit lines respectively. Computer processing techniques typically involve processing bits in groups which are referred to as words. For example, a 64 bit processor may operate on groups of bits that are 64 bits in length. A word line, which corresponds to a row line (404), is connected to each bit within a word. A bit line, which corresponds to a column line (402), is connected to a particular bit along each word line.

The memory controller of the crossbar array may be designed to operate by reading and writing words. A memory controller is a digital circuit designed to manage the flow of data into and out of a memory array. Thus, during a read process, the crossbar array may read the state of each bit along a word line simultaneously. Although the example illustrated in FIG. 4 shows only four memory elements (408) along a word line, a crossbar array embodying principles described herein may include a larger number of memory elements along a word line.

To sense the state of the memory elements (408) along a row line, that row line (404-1) will be selected. When a row line (404-1) is selected, the switches (416) will be set such that the oscillating signal supply (406) as well as the DC signal supply (414-1) will be connected to the selected row line. These signal supplies (406, 414-1) will apply an oscillating signal that is offset with a DC signal. Additionally, the unselected row lines (404-2) will be connected to a second DC signal supply (414-2). This second DC signal supply will apply a DC signal to each of the unselected row lines (404-2). The value of the DC signal from the second DC signal supply (414-2) is the same value as the signal applied to the selected row line (404-1) by the first DC signal supply (414-1).

Applying a DC signal from another source to the unselected row lines (404-2) reduces the leakage current passing through the crossbar array to a negligible level. This is because the DC voltage level at both ends of each memory element (408) is the same. If there is no difference in voltage at both ends of a memory element (408), then no leakage current will be present. Leakage current refers to the electric current that flows through memory elements in the crossbar array that are not being selected for sensing. This leakage current adversely affects the process of sensing the memory elements that are selected. Because the leakage current is eliminated, only the selected row line (404-1) experiences the AC signal. Thus, the oscillating signal as sensed by the sensing circuitry connected to the column lines (404) will only be affected by memory elements along the selected row line (404-1).

An oscillating signal may be for example, a standard Alternating Current (AC) signal. Throughout this specification and in the appended claims, the term signal may be an electrical signal either in a voltage or current form. Thus, an oscillating signal supply may be either an AC voltage supply or an AC current supply.

With the oscillating signal applied to a row line, sensing circuitry connected to the crossbar array though bond pads (410) may sense the AC signal flowing the column lines (402). In the case where each memory element along the row line is being read simultaneously, the sensing circuitry can sense the oscillating signal flowing from each of the column lines (402).

As described above, the oscillating signal being sensed from a memristive memory element will be attenuated based on the state of the memristive device. Thus, the state of each memory element (208) along the selected row line (404-1) may be determined based on the attenuation of the oscillating signal being sensed from the respective column lines (402). Because there is no need to isolate each memory element with additional circuitry, the crossbar array may take up less space when manufactured onto a chip.

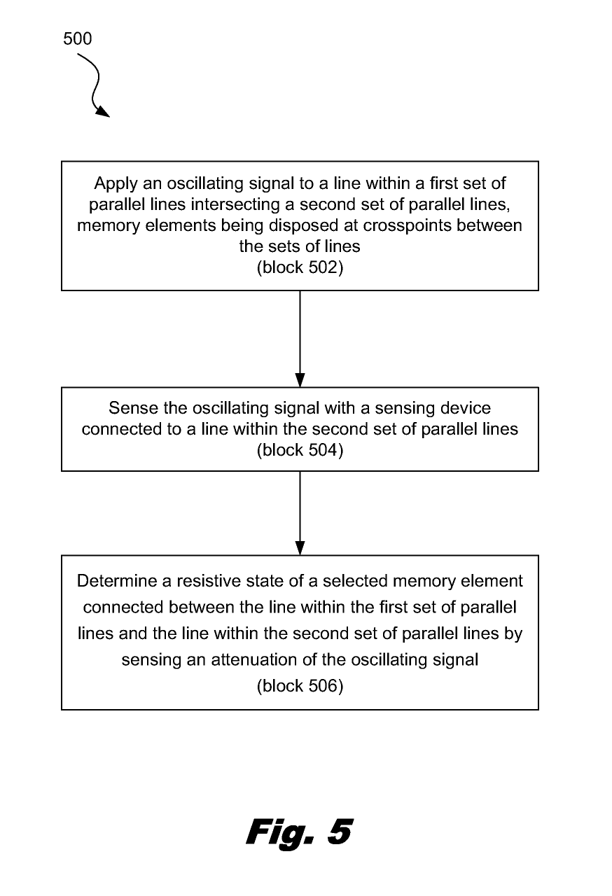

FIG. 5 is a flowchart showing an illustrative method for using an oscillatory signal to sense the state of a memristive device. According to certain illustrative examples, the method includes applying (block 502) an oscillating signal to a line within a first set of parallel lines intersecting a second set of parallel lines, memory elements being disposed at crosspoints between the sets of lines, sensing (block 504) the oscillating signal with a sensing device connected to a line within the second set of parallel lines, and determining (block 506) a resistive state of a selected memory element connected between the line within the first set of parallel lines and the line within the second set of parallel lines by sensing an attenuation of the oscillating signal. The frequency of the oscillating signal is greater than a corner frequency of a low pass filter comprising the selected memory element in a high resistive state and the frequency is lower than a corner frequency of the low pass filter when the selected memory is in a low resistive state

In conclusion, through use of methods and systems embodying principles described herein, the resistive state of a memristive device can be determined through use of an oscillating signal. When used to determine the state of memristive memory elements in a crossbar array, no circuitry is needed to isolate selected memory elements from leakage currents. Thus, the crossbar array will consume less power and take up less space.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A memory device capable of being sensed with an oscillating signal, the device comprising:
a first terminal of a memristive element connected to an oscillating signal supply; and
a second terminal of said memristive element connected to sensing circuitry, said sensing circuitry to determine an attenuation of an oscillating signal from said oscillating signal supply.

2. The device of claim 1, in which a corner frequency of a low pass filter comprising said memristive element in a high state is lower than a frequency of said oscillating signal.

3. The device of claim 2, in which a corner frequency of a low pass filter comprising said memristive element in a low resistive state is greater than said frequency of said oscillating signal.

4. The device of claim 1, in which a capacitance of a low pass filter comprising said memristive element is created using a discrete capacitor.

5. The device of claim 1, further comprising a non-oscillating signal supply connected to said first terminal, said non-oscillating signal supply to apply a non-oscillating signal to said memristive element in addition to said oscillating signal.

6. The device of claim 1, in which said sensing circuitry comprises a peak detector.

7. The device of claim 1, in which said sensing circuitry comprises a sample and hold circuit.

8. A crossbar array comprising:
a first set of parallel lines selectively connected to an oscillating signal supply;
a second set of parallel lines intersecting said first set of parallel lines, said second set of parallel lines selectively connected to sensing circuitry;
memristive memory elements being disposed at crosspoints between said first set of parallel lines and said second set of parallel lines;
in which a memory controller of said crossbar array is to determine a resistive state of one of said memory elements by determining, with said sensing circuitry, an attenuation of an oscillating signal produced by said oscillating signal supply.

9. The crossbar array of claim 8, in which a corner frequency of a low pass filter comprising said one of said memristive memory elements in a high resistive state is lower than a frequency of said oscillating signal.

10. The crossbar array of claim 8, in which a corner frequency of a low pass filter comprising said one of said memristive memory elements in a low resistive state is greater than a frequency of said oscillating signal.

11. The crossbar array of claim 8, in which a capacitance of a low pass filter comprising said one of said memristive memory element is created using a discrete capacitor.

12. The crossbar array of claim 8, further comprising a non-oscillating signal supply connected to said first set of parallel lines, said non-oscillating signal supply to supply a non-oscillating signal to said memristive memory elements in addition to said oscillating signal.

13. The crossbar array of claim 8, in which said sensing circuitry comprises a peak detector.

14. The crossbar array of claim 8, in which said sensing circuitry comprises a sample and hold circuit.

15. A method for sensing the resistive state of a memory element within a crossbar array using an oscillating signal, the method comprising:
applying an oscillating signal to a line within a first set of parallel lines intersecting a second set of parallel lines, memory elements being disposed at crosspoints between said sets of lines;
sensing said oscillating signal with a sensing device connected to a line within said second set of parallel lines; and
determining a resistive state of a selected memory element connected between said line within said first set of parallel lines and said line within said second set of parallel lines by sensing an attenuation of said oscillating signal;
in which a frequency of said oscillating signal is greater than a corner frequency of a low pass filter comprising said selected memory element in a high resistive state and said frequency is lower than a corner frequency of said low pass filter when said selected memory is in a low resistive state.
